(19) United States
(12) Patent Application Publication
(10) Pub. No.: US 2005/0231246 A1
(43) Pub. Date: Oct. 20, 2005

(54) Power-up detector

(75) Inventors: Chang Seok Kang, Gyeonggi-do (KR); Jae Jin Lee, Gyeonggi-do (KR)

Correspondence Address: HELLER EHRMAN WHITE & MCAULIFFE LLP, 1717 RHODE ISLAND AVE, NW, WASHINGTON, DC, 20036-3001, US

(73) Assignee: Hynix Semiconductor Inc., Gyeonggi-do (KR)

(21) Appl. No.: 11/166,725

(22) Filed: Jun. 27, 2005

Related U.S. Application Data
(62) Division of application No. 10/737,960, filed on Dec. 18, 2003.

(30) Foreign Application Priority Data
Mar. 28, 2003 (KR) 10-2003-0019589

(51) Int. Cl. H03L 7/00

(52) U.S. Cl. 327/143

(57) ABSTRACT

A power-up detector comprises a voltage divider for dividing a power voltage in a predetermined ratio, and a potential detector for comparing a predetermined potential with a potential divided by the voltage divider, and outputting the comparison result. Although the state of an external power voltage, which is inputted after a power-up signal is generated when a power voltage rises over a predetermined level, is changed by noise, the level of the power-up signal is not changed unless the power voltage falls below a predetermined level. Accordingly, a semiconductor device can be stably initialized.

### BACKGROUND OF THE INVENTION

1. Field of the Invention

The present invention generally relates to a power-up detector, and more specifically, to a power-up detector for stably detecting when a power voltage is over a predetermined level without being affected by noise.

2. Description of the Prior Art

Generally, a power-up detector detects a power voltage applied externally to initialize a semiconductor device before the power voltage is over a predetermined level and to operate the semiconductor device when the power voltage is over a predetermined level.

FIG. 1 is a circuit diagram of a conventional power-up detector.

The conventional power-up detector comprises a voltage divider 1, a potential detection unit 2, an inverter INV1 and a buffer 3. The voltage divider 1 divides a power voltage VCC in a predetermined ratio. The potential detection unit 2 detects a potential N0 divided by the voltage divider 1. The inverter INV1 inverts a potential N1 detected by the potential detection unit 2. The buffer 3 buffers a signal N2 outputted from the inverter INV1, and outputs a power-up detecting signal PWR.

The voltage divider 1 comprises resistors R1 and R2 connected in series between the power voltage VCC and a ground voltage. The potential N0 is outputted at a common node of the resistors R1 and R2.

The potential detection unit 2 comprises a resistor R3 connected in series between the power voltage VCC and the ground voltage, and a NMOS transistor NM1 having a gate to receive the potential N0. The potential N1 is outputted at a common node of the resistor R3 and the NMOS transistor NM1.

The buffer 3 comprises inverters INV2 and INV3 for sequentially inverting the signal N2 outputted from the inverter INV1.

Hereinafter, the operation of the conventional power-up detector is described.

When an external power voltage VCC is applied to a chip, the conventional power-up detector detects a potential of the external power voltage VCC, and outputs a power-up signal PWR when the external power voltage VCC reaches a predetermined potential.

The power-up signal PWR precharges specific nodes or circuits to high or low levels until an internal voltage is set up to a predetermined level for initialization of the chip, that is for stabilization of the internal power.

However, as shown in FIGS. 2a and 2b, if the external power voltage VCC is inputted with ripple noise, the state of the power-up signal PWR toggles whenever the external power voltage VCC reaches a predetermined potential V1, thereby increasing power consumption and causing mis-operation.

As the power voltage decreases, the interval between the power voltage level where the power-up signal is generated and the operation voltage level becomes smaller. When noise is generated in the power voltage, an undesired power-up signal PWR is generated, thereby initializing the semiconductor device.

### SUMMARY OF THE INVENTION

Accordingly, it is an object of the present invention to provide a power-up detector wherein a level of a power-up signal is not changed although an external power voltage inputted after the power-up signal is generated toggles by noise, thereby stably initializing a semiconductor device.

In an embodiment of the present invention, a power-up detector comprises a voltage divider and a potential detector. The voltage divider divides a power voltage in a predetermined ratio. The potential detector compares a predetermined potential with a potential divided by the voltage divider, and outputs the comparison result. The above voltage divider comprises a resistance regulator for changing the predetermined ratio depending on the comparison result outputted from the potential detector.

In another embodiment of the present invention, a power-up detector comprises a voltage divider, a potential detector, a buffer and a potential maintainer. The voltage divider divides a power voltage in a predetermined ratio. The potential detector compares a predetermined potential with a potential divided by the voltage divider, and outputs the comparison result. The buffer stabilizes the comparison result outputted from the potential detector, and outputs a power-up signal. The potential maintainer sets up an output terminal of the potential detector at a predetermined potential depending on the power-up signal.

### BRIEF DESCRIPTION OF THE DRAWINGS

FIG. 1 is a circuit diagram of a conventional power-up detector.

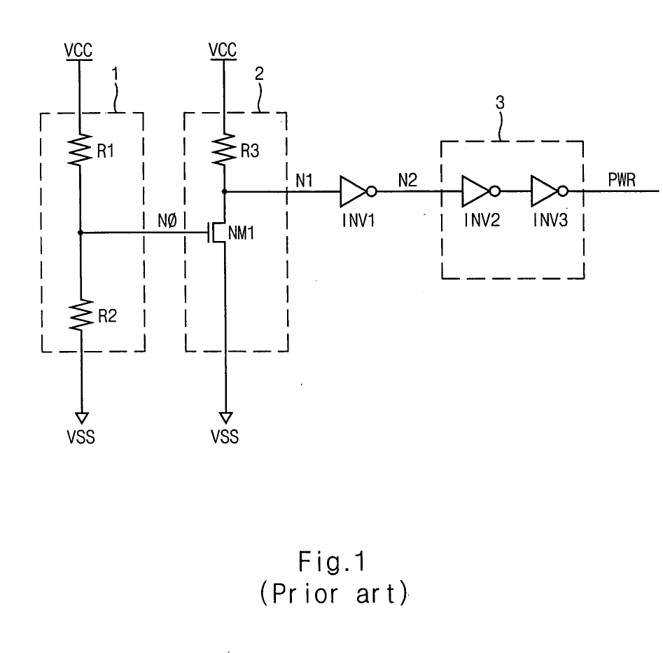

FIGS. 2a and 2b are a timing diagram of the power-up detector of FIG. 1.

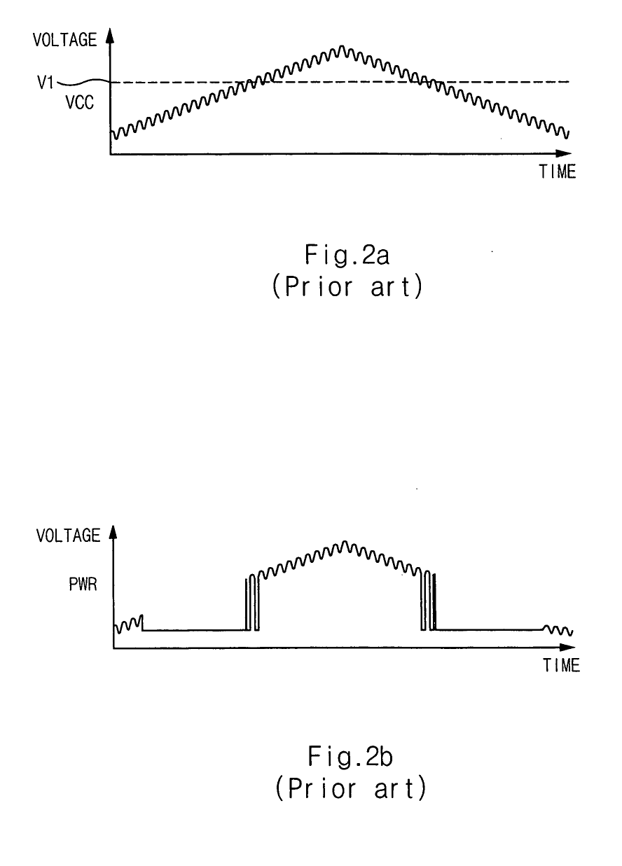

FIG. 3 is a circuit diagram of a power-up detector according to an embodiment of the present invention.

FIGS. 4a and 4b are a timing diagram of the power-up detector of FIG. 3.

FIGS. 5a and 5b are a timing diagram of the power-up detector of FIG. 3 when a ripple is generated in a power voltage.

FIG. 6 is a circuit diagram of a power-up detector according to another embodiment of the present invention.

### DETAILED DESCRIPTION OF THE PREFERRED EMBODIMENTS

The present invention will be described in detail with reference to the accompanying drawings.

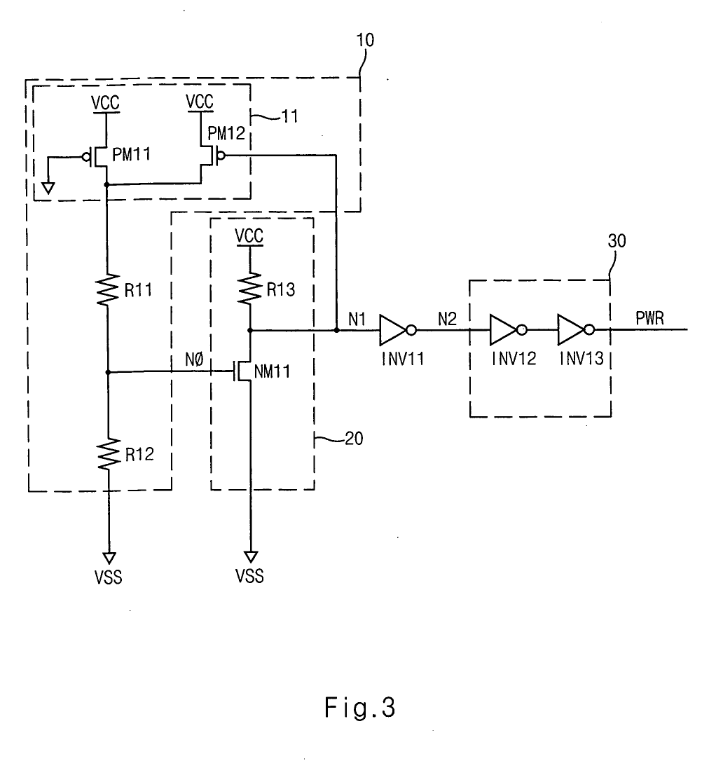

FIG. 3 is a circuit diagram of a power-up detector according to an embodiment of the present invention.

In an embodiment, the power-up detector comprises a voltage divider 10, a potential detection unit 20, an inverter INV11 and a buffer unit 30. The voltage divider 10 divides a power voltage VCC in a predetermined ratio. The potential detection unit 20 compares a predetermined potential with a potential N0 divided by the voltage divider 10, and outputs the comparison result N1. The inverter INV11 inverts the comparison result N1. The buffer unit 30 sequentially inverts a signal N2 outputted from the inverter INV11, and outputs a power-up signal PWR.

The voltage divider 10 comprises resistors R11 and R12, and a resistance regulator 11. The resistor R11 is connected in series to the resistance regulator 11 between the power voltage VCC and an output terminal N0. The resistor R12 is connected between the output terminal N0 and a ground voltage VSS. A divided potential N0 is outputted at a common node N0 of the resistors R11 and R12.

The resistance regulator 11 comprises PMOS transistors PM11 and PM12 connected in parallel between the power voltage VCC and the resistor R11. The PMOS transistor PM11 has a gate connected to the ground voltage VSS. The PMOS transistor PM12 has a gate connected to the output terminal N1 of the potential detection unit 20. The resistance regulator 11 may regulate resistance values depending on the potential of the output terminal N1.

The potential detection unit 20 comprises a resistor R13 and a NMOS transistor NM11. The comparison result N1 is outputted at a common node of the resistor R13 and the NMOS transistor NM11 connected in series between the power voltage VCC and the ground voltage VSS. The NMOS transistor NM11 has a gate to receive the potential N0.

The buffer unit 30 comprises inverters INV12 and INV13 for sequentially inverting a potential N2 and stabilizing the potential of the power-up signal PWR.

The voltage divider 10 divides the power voltage VCC depending on ratio of the resistances. The potential N0 divided by the voltage divider 10 is represented by the following Equation 1.

$$N0 = \frac{Rdn}{Rup + Rdn} \times VCC \qquad [ Equation 1 ]$$

The pull-up resistance value Rup is the sum of resistances between the power voltage VCC and the output terminal N0, and the pull-down resistance value Rdn is the resistance value between the output terminal N0 and the ground voltage VSS. Here, the Rup is the sum of the resistance value Rt of the resistance regulator 11 and the resistance value of the resistor R11, and the Rdn is the resistance value of the resistor R12.

The resistance regulator 11 comprises the PMOS transistors PM11 and PM12 connected in parallel between the power voltage VCC and the resistor R11.

The PMOS transistor PM11 having gate connected to the ground voltage VSS is always turned on to serve as a resistance device.

The PMOS transistor PM12 having a gate to connected to the output terminal N1 of the potential detection unit is turned on to serve as a resistance device or turned off to serve as a switch device depending on the potential of the output terminal N1.

When the potential N0 divided by the voltage divider is lower than a threshold voltage Vtn of the NMOS transistor NM11 of the potential detection unit 20 because the level of the power voltage VCC is low, the NMOS transistor NM11 is maintained at a turn-off state. As a result, the potential of the output terminal N1 of the potential detection unit 20 becomes at a high level.

When the potential of the output terminal N1 is at the high level, the PMOS transistor PM12 of the resistance regulator 11 is maintained at a turn-off state. As a result, the resistance value Rt of the resistance regulator is the same as the resistance value Rpm11 when the PMOS transistor PM11 is turned on.

The potential N0 divided by the voltage divider 10 is represented by Equation 2.

$$\begin{matrix}N0 = \frac{Rdn}{Rup + Rdn} \times VCC \\ = \frac{R12}{Rt + R11 + R12} \times VCC \\ = \frac{R12}{Rpm11 + R11 + R12} \times VCC\end{matrix} \qquad [ Equation 2 ]$$

The high level potential of the output terminal N1 of the potential detection unit 20 is inverted by the inverter INV11, and stabilized by the buffer unit 30 to be outputted as a power-up signal PWR having a low level.

When the potential N0 divided by the voltage divider is higher than the threshold voltage Vtn of the NMOS transistor NM11 of the potential detection unit 20, the NMOS transistor NM11 is turned on. As a result, the potential of the output terminal N1 of the potential detection unit 20 becomes at a low level.

When the potential of the output terminal N1 of the potential detection unit 20 is at the low level, the PMOS transistor PM12 of the resistance regulator 11 is turned on. The resistance value Rt of the resistance regulator 11 is a resistance value where a resistance value Rpmll when the PMOS transistor PM11 is turned on and a resistance value Rpm12 when the PMOS transistor PM12 is turned on are connected in parallel. The resistance value Rt of the resistance regulator 11 is represented by Equation 3.

$$Rt = \frac{Rpm11 \times Rpm12}{Rpm11 + Rpm12} \qquad [ Equation 3 ]$$

The resistance value Rt of the resistance regulator 11 which serves as a resistance device when the PMOS transistor PM12 of the resistance regulator 11 is turned on is smaller than that of the resistance regulator 11 which serves as a switch device when the PMOS transistor PM12 of the resistance regulator 11 is turned off.

As a result, since the pull-up resistance value Rup becomes smaller, the potential NO divided by the voltage divider 10 increases.

At the same level of the power voltage VCC, the potential NO divided by the voltage divider 10 when the PMOS transistor PM12 is turned off is higher than when the PMOS transistor PM12 is turned on.

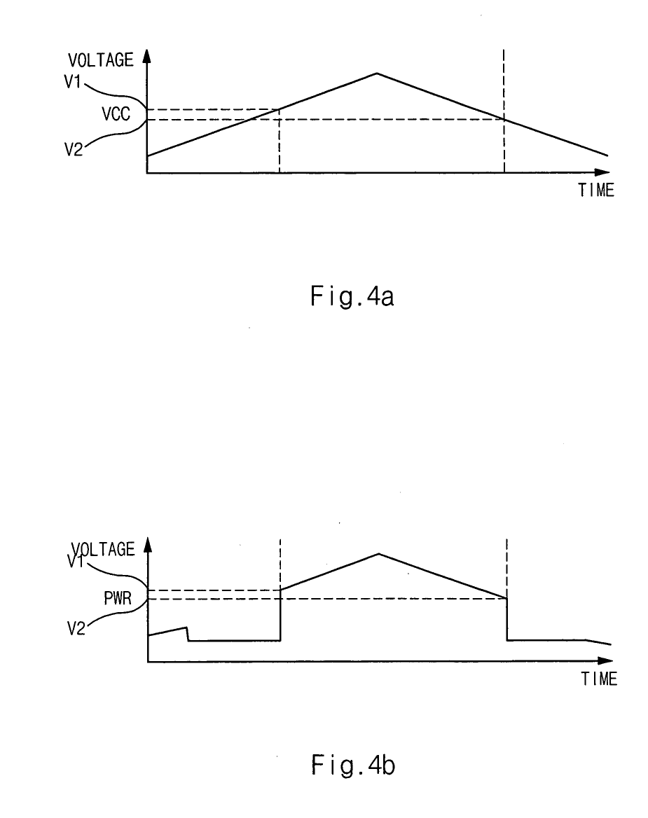

FIG. 4a is a timing diagram of the power voltage VCC of FIG. 3. The power voltage VCC level where the potential NO divided by the voltage divider 10 becomes the threshold voltage Vtn of the NMOS transistor NM11 of the potential detection unit 20 becomes lower when the PMOS transistor PM12 of the resistance regulator 11 is turned on (V1) than when the PMOS transistor PM12 of the resistance regulator 11 is turned off (V2).

FIG. 4b is a timing diagram of the power up signal PWR of FIG. 3, when the power voltage VCC is like FIG. 4a.

Although the power voltage VCC level toggles by noise and ripple after the power up signal PWR becomes at the high level when the NMOS transistor NM11 is turned on, the level of the power-up signal PWR is not changed if the potential NO is higher than the threshold voltage Vtn of the NMOS transistor NM11.

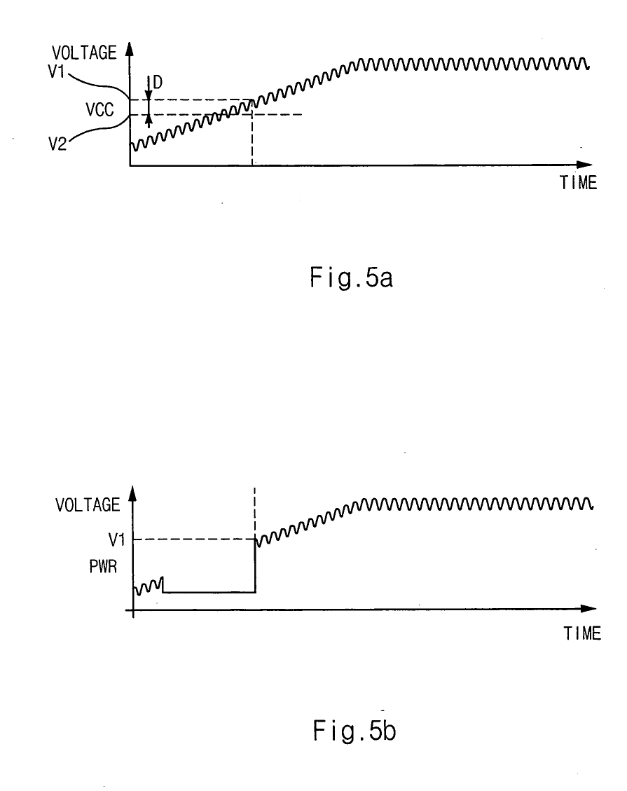

FIG. 5a is a timing diagram of the power voltage VCC of FIG. 3 when a ripple is generated in a power voltage.

If the power voltage VCC level rises, the potential NO, which is divided by the voltage divider 10 when the PMOS transistor PM12 is turned off, turns on the NMOS transistor NM11 of the potential detection unit 20. As a result, the power-up signal PWR becomes at the high level.

FIG. 5b is a timing diagram of the power up signal PWR of the FIG. 3 when the power voltage VCC is like FIG. 5a.

Thereafter, since the pull-up resistance value Rup of the voltage divider 10 becomes smaller when the PMOS transistor PM12 of the resistance regulator 11 is turned on, the power-up signal PWR is maintained at the high level although the power voltage VCC level toggles by noise or riffle.

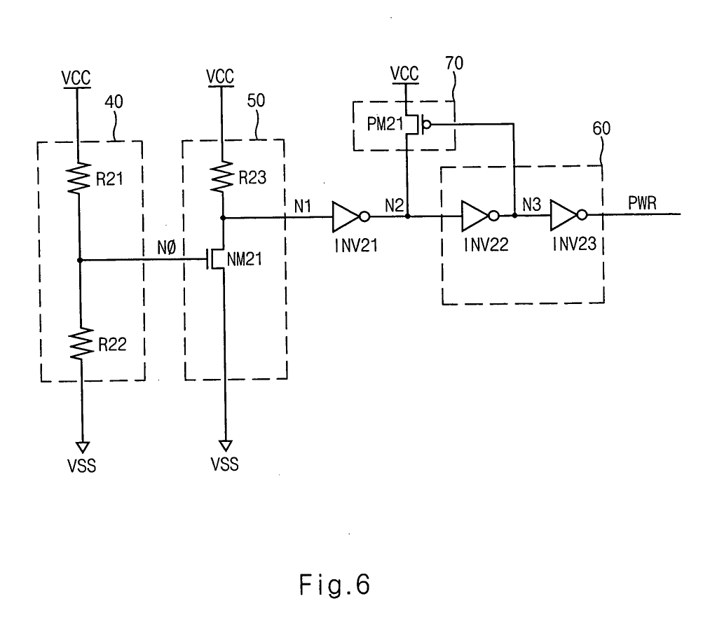

FIG. 6 is a circuit diagram of a power-up detector according to another embodiment of the present invention.

In another embodiment, the power-up detector comprises a voltage divider 40, a potential detection unit 50, an inverter INV21, a buffer unit 60 and a pull-up unit 70. The voltage divider 40 divides a power voltage VCC in a predetermined ratio. The potential detection unit 50 compares a divided potential with a predetermined potential, and outputs the comparison result N1. The inverter INV21 inverts the comparison result N1. The buffer unit 60 sequentially inverts a signal N2 outputted from the inverter INV21, and outputs a power-up signal PWR. The pull-up unit 70 pulls up the input terminal N2 of the buffer unit 60 depending on a signal having the opposite phase of the power-up signal PWR.

The voltage divider 40 comprises resistors R21 and R22 connected in series between the power voltage VCC and a ground voltage. A potential NO is outputted at a common node of the resistors R21 and R22.

The potential detection unit 50 comprises a resistor R23 and NMOS transistor NM21 connected in series between the power voltage VCC and the ground voltage VSS. The NMOS transistor NM21 has a gate to receive the potential NO divided by the voltage divider 40. The comparison result potential N1 is outputted from a common node of the resistor R23 and the NMOS transistor NM21.

The buffer unit 60 comprises inverters INV22 and INV23 for sequentially inverting the potential N2 outputted from the inverter INV21 to stabilize the potential of the power-up signal PWR.

The pull-up unit 70 comprises a PMOS transistor PM21 having a gate connected to an output terminal N3 of the inverter INV22 of the buffer unit 60.

When the power-up signal PWR is at a low level, the PMOS transistor PM21 is maintained at a turn-off state. As a result, the power-up signal PWR transits to a high level at a predetermined potential V1 of the power voltage VCC.

While the power-up signal PWR is at the high level, the PMOS transistor PM21 of the pull-up unit 70 is maintained at a turn-on state. As a result, the power-up signal PWR transits to the low level at a voltage V2 which is lower than the predetermined potential V1 of the power voltage VCC where the power-up signal PWR transits to the high level.

Although the power-up signal PWR transits from the low to high level at the predetermined potential V1 of the power voltage VCC, and the power voltage VCC falls to a lower voltage than the predetermined potential V1 by noise or riffle, the PMOS transistor PM21 of the pull-up unit 70 is maintained at the turn-on state. As a result, the power-up signal PWR does not transit to the low level unless the power voltage VCC becomes lower than a predetermined potential V2.

Instead of the PMOS transistor PM21 of the pull-up unit 70 which pulls up the input terminal N2 of the buffer unit 60 to the high level, a pull-down unit may be used which is controlled by a signal having the same phase of the power-up signal PWR to pull down the output terminal N1 of the potential detection unit 50 to a low level. Here, the pull-down unit may comprise a NMOS transistor having a gate to receive a signal having the same phase of the power-up signal PWR.

As discussed earlier, in a power-up detector according to an embodiment of the present invention, although the state of an external power voltage, which is inputted after a power-up signal is generated when a power voltage rises over a predetermined level, is changed by noise, the level of the power-up signal is not changed unless the power voltage falls below a predetermined level. Accordingly, a semiconductor device can be stably initialized.

1-5. (canceled)

6. A power-up detector comprising:
a voltage divider for dividing a power voltage in a predetermined ratio;
a potential detector for comparing a predetermined potential with a potential divided by the voltage divider, and outputting the comparison result;
a buffer for stabilizing the comparison result outputted from the potential detector, and for outputting a power-up signal; and
a potential maintainer for setting an output terminal of the potential detector at a predetermined potential depending on the power-up signal.

7. The power-up detector according to claim 6, wherein the potential maintainer comprises a pull-up means for setting an output terminal of the potential detector at the power voltage depending on the power-up signal.

8. The power -up detector according to claim 6, wherein the potential maintainer comprises a pull-down means for setting an output terminal of the potential detector at a ground voltage depending on the power-up signal.
